(19) United States
(12) Patent Application Publication
(10) Pub. No.: US 2006/0151320 A1
(43) Pub. Date: Jul. 13, 2006

(54) Tubular sputtering target

(76) Inventors: Martin Weigert, Hanau (DE); Markus Schultheis, Flieden (DE); Martin Schlott, Offenbach (DE); Christoph Simons, Biebergemund (DE)

Correspondence Address: Wolff & Samson PC, One Boland Drive, West Orange, NJ, 07052, US

(21) Appl. No.: 11/293,544

(22) Filed: Dec. 2, 2005

(30) Foreign Application Priority Data
Dec. 2, 2004 (DE) 10 2004 058 316.1

(51) Int. Cl. C23C 14/00

(52) U.S. Cl. 204/298.12; 204/298.13

(57) ABSTRACT

A tubular sputtering target with a target body and with an attachment device arranged at at least one end of the target body. The attachment device and/or an end cover are joined with the target body by material joining or positive locking.

### BACKGROUND OF THE INVENTION

The invention concerns a tubular sputtering target with a target body and with an attachment device arranged on at least one end of the tube.

Many sputtering targets of this type are known, e.g., those described in WO 97/15697, DE 100 43 748, and DE 100 63 383. A tubular sputtering target of this type can be formed either as a self-supporting target from the material to be sputtered or as a support tube coated with the material to be sputtered.

In practice, thin coatings of molybdenum alloys for optical functional coatings are becoming increasingly important, especially in the coating or large glass surface areas and in the coating of flat screens. Coatings of this type are generally produced by sputtering, and tubular targets are being used to greater and greater extent, since they allow a higher sputtering yield and produce more uniform results. It is precisely molybdenum or molybdenum alloys (especially molybdenum-base alloys) that are used here. They are applied to support tubes as sputtering target material and soldered on to them to achieve sufficient stability of the tubular sputtering target. These designs, in which high-grade steel is usually used as the support tube material, have a limited capacity for heat absorption and dissipation, since the soldered connection often does not withstand the thermal stresses. However, if the solder melts and escapes to the outside from peripheral gaps, the sputtering target can no longer be used.

### SUMMARY OF THE INVENTION

Accordingly, it is an object of the present invention to solve this problem of the prior art constructions. Pursuant to this object, one aspect of the present invention resides in a tubular sputtering target having a target body and an attachment device arranged at at least one end of the body. The attachment device and/or an end cover is joined with the target body by material joining or positive locking.

As a result of the fact that the attachment device and/or a tube end cover is connected with the support body by positive locking or by material joining, first, the problems that arise from the otherwise necessary soldering process between the sputtering material and the support tube are avoided, and, second, the necessary mechanical strength is produced by the stabilization of the ends of the tube, and the necessary vacuum tightness is also produced by the connection by means of positive locking or material joining, especially if the target body extends almost completely over the cross section of the tube.

In particular, it is advantageous if the target body is made of metal, preferably titanium, molybdenum, niobium, chromium, tungsten, aluminum, copper, zirconium, tantalum, nickel, silver, or an alloy of at least one of these metals. Furthermore, it is advantageous if the attachment device (preferably designed as a flange) and/or the tube end cover is made of titanium, molybdenum, tungsten, chromium, aluminum, silver, nickel, zinc, copper, zirconium, vanadium, niobium, tantalum, or an alloy of at least one of these metals, since, first, these materials can be joined well with the target material, and, second, they guarantee the necessary stability and heat dissipation. Alloys of titanium with one or more metals of the group comprising aluminum, tin, copper, zirconium, vanadium, and molybdenum are especially well suited. Preferred alloys are titanium-aluminum-tin, titanium-copper, titanium-aluminum-zirconium, titanium-aluminum-vanadium, and titanium-aluminum molybdenum alloys. The material of the support body preferably can have about 0.5 wt. % to about 5 wt. % chromium or tungsten. Furthermore, it is advantageous for the target body and the attachment device and/or the tube end cover to be made of the same material. It is also advantageous for the attachment device and/or the tube end cover to be soldered or welded onto the target body, especially by electron beam welding. The target body can be produced by shaping, especially extrusion or flowforming of a target blank.

Sputtering targets of this type can be subjected to energetically larger loads than the previously known support tube/sputter layer designs described above, since they have better thermal conductivity. Compared to the previously known tubes, they can be subjected to energetic loads about 1.5 times greater. The coatings produced with the sputtering targets of the invention have good transmission, reflection, and coating resistance values.

Other features and advantages of the present invention will become apparent from the following description of the invention that refers to the accompanying drawings.

### BRIEF DESCRIPTION OF THE DRAWINGS

FIG. 1 shows a tubular target supported at one end.

FIG. 2 shows a tubular target supported at both ends.

### DETAILED DESCRIPTION OF THE INVENTION

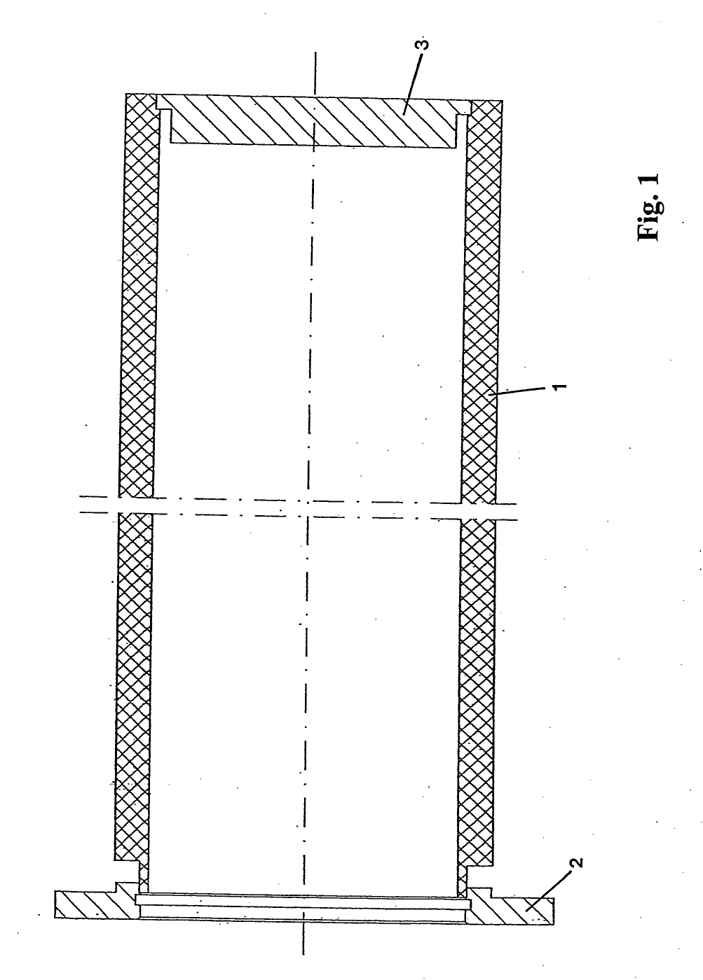

Tubular targets can be supported in the sputtering installation either at one end or at both ends. The inside of the tube is sealed vacuum-tight from the outside environment. The target/support body 1 is made of molybdenum, possibly alloyed with about 0.5 wt.% to about 5 wt. % chromium or tungsten. In the case of a tubular target supported at one end (FIG. 1), an attachment flange 2 is welded vacuum-tight to only one end of the tube by the electron beam welding process, while the other end is joined vacuum-tight with a tube end cover 3 by electron beam welding.

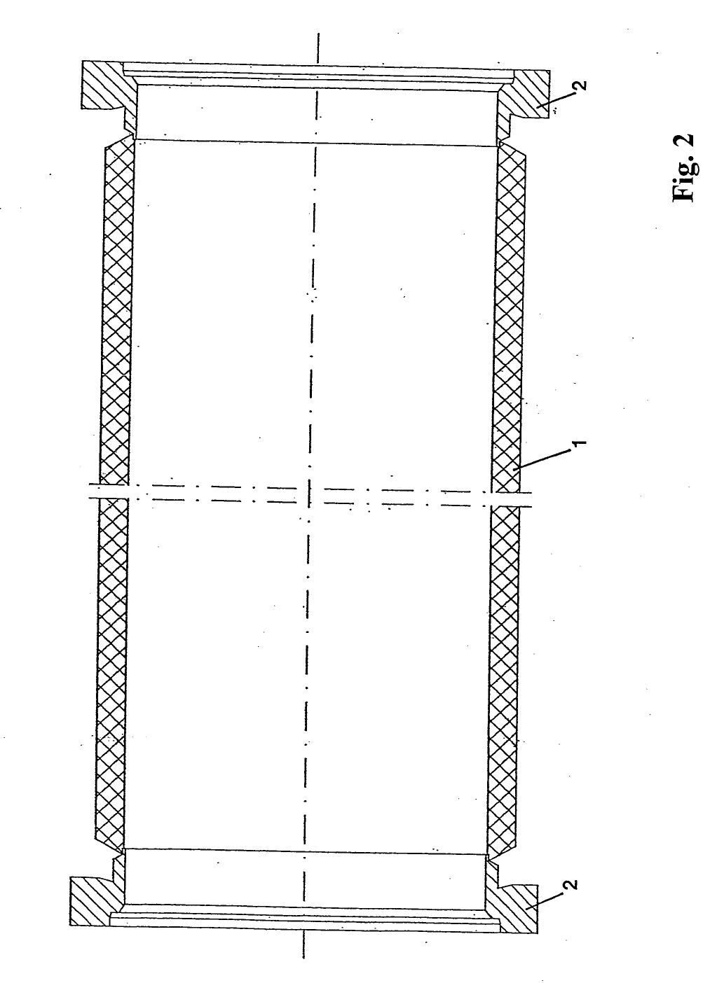

In the case of a tubular target supported at both ends (FIG. 2), and attachment flange 2 is welded onto both ends of the support body 1. Here again, the joint is vacuum-tight and is preferably produced by the electron beam welding process. The titanium alloys specified above are especially suitable materials for the tube end cover 3 or the attachment flange 2.

Molybdenum can be used, for example, as a sputtering material for back contacts in photovoltaic cells (large-area coating) or as a diffusion barrier between aluminum and silicon in display coating. Titanium can be used, for example, to form highly refractive titanium dioxide coatings or as a diffusion barrier. Chromium can be used, for example, as a reflector or a CrN absorber in glass coating or in black-matrix displays. Niobium can be used, for example, in glass coating to form highly refractive Nb₂O₅ coatings. Tungsten finds use as a sputtering material, for example, as tungsten oxide in electrochromic applications.

Although the present invention has been described in relation to particular embodiments thereof, many other variations and modifications and other uses will become apparent to those skilled in the art. It is preferred, therefore, that the present invention be limited but by the specific disclosure herein, but only by the appended claims.

1. A tubular sputtering target, comprising: a target body; and an attachment device arranged at at least one end of the body, the attachment device and/or an end cover being joined with the target body by material joining or positive locking.

2. The tubular sputtering target in accordance with claim 1, wherein the target body extends almost completely over a cross section of the tubular target.

3. The tubular sputtering target in accordance with claim 1, wherein the target body is made of metal.

4. The tubular sputtering target in accordance with claim 3, wherein the target body is made of titanium, molybdenum, niobium, chromium, tungsten, aluminum, copper, zirconium, tantalum, nickel, silver or an alloy of at least one of these metals.

5. The tubular sputtering target in accordance with claim 1, wherein the attachment device and/or the end cover is made of titanium, molybdenum, tungsten, chromium, aluminum, silver, nickel, zinc, copper, zirconium, vanadium, niobium, tantalum or an alloy of at least one of these metals.

6. The tubular sputtering target in accordance with claim 5, wherein the attachment device and/or the end cover is made of titanium alloy that comprises titanium and at least one metal of the group consisting of aluminum, tin, copper, zirconium, vanadium, and molybdenum.

7. The tubular sputtering target in accordance with claim 1, wherein the target body and the attachment device and/or the end cover are made of the same material.

8. The tubular sputtering target in accordance with claim 1, wherein the attachment device and/or the end cover is soldered or welded onto the target body.

9. The tubular sputtering target in accordance with claim 8, wherein the attachment device and/or the end cover is electron beam welded onto the target body.

10. The tubular sputtering target in accordance with claim 1, wherein the attachment device is a flange.

11. The tubular sputtering target in accordance with claim 1, wherein the target body contains about 0.5 wt. % to about 5 wt. % chromium and/or tungsten.
